(19) United States
(12) Patent Application Publication
(10) Pub. No.: US 2007/0117393 A1
(43) Pub. Date: May 24, 2007

(54) Hardened porous polymer chemical mechanical polishing (CMP) pad

(76) Inventors: Alexander Tregub, San Jose, CA (US); Satish Narayanan, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/284,486

(22) Filed: Nov. 21, 2005

(51) Int. Cl. C03C 15/00; H01L 21/461; B24D 11/02; H01L 21/302

(52) U.S. Cl. 438/692; 51/294; 216/88

(57) ABSTRACT

A batch of porous polymer chemical-mechanical polishing (CMP) pads for shipment is described. The CMP pads within the batch are for or use in a semiconductor chip manufacturing process. The CMP pads within the batch exhibit an average dynamic modulus within a range of 65 MPa to 80 MPa inclusive when measured at 100 Hz.

### FIELD OF INVENTION

The field of invention relates generally to semiconductor chip manufacturing, and, more specifically, to a hardened porous polymer Chemical Mechanical Polishing (CMP) pad.

### BACKGROUND

In the art of semiconductor chip manufacturing, many semiconductor chips are manufactured together upon a single semiconductor wafer. Semiconductor manufacturing processes tend to be applied more to the wafer as whole rather than specific semiconductor chips individually. When the manufacturing processes that are applied to a semiconductor wafer are complete, the wafer is subsequently “diced” into multiple (typically identically designed) semiconductor chips.

A semiconductor chip can be viewed as a “multi-level” structure having, at a number of different instances (e.g., at each level in the multi-level structure), a layer of electrically conducting material that is disposed upon a layer of dielectric. The stacked layers of dielectric and electrically conducting materials are pattered in some fashion in order to form the semiconductor chip's transistor interconnect wiring. In order to form interconnect wiring or other structures (e.g., shallow trench isolation) of sufficient electrical and structural quality, it is important that the metallic and/or dielectric layers in the multi-level structure be “flat”. As a consequence, the semiconductor industry has developed technologies devoted to the formation of highly planar metallic surfaces and highly planar dielectric surfaces.

One of these technologies, referred to as chemical mechanical polishing (CMP), “planarizes” a metallic or dielectric surface through a combination of chemical reaction and mechanical polishing. As a simplistic perspective of CMP, a pad and slurry is applied to the wafer surface to be planarized. The polishing away of materials on the wafer surface is accomplished through both mechanical brushing action on the wafer surface with the pad (typically in conjunction with abrasive particles resident in the slurry), and, a chemical reaction on the surface imposed by the specific chemistry of the slurry. The result is a highly smooth surface.

### BRIEF DESCRIPTION OF THE DRAWINGS

The present invention is illustrated by way of example and not limitation in the figures of the accompanying drawings, in which like references indicate similar elements and in which:

FIG. 1 shows a cross section of a hard poromeric CMP pad;

FIG. 2 shows a correlation between dishing observed on a Cu surface and CMP pad dynamic modulus;

FIG. 3 storage modulus change as a function of applied baking temperature;

FIG. 4 (prior art) shows a depiction of CMP equipment that could execute the methodology of FIG. 2.

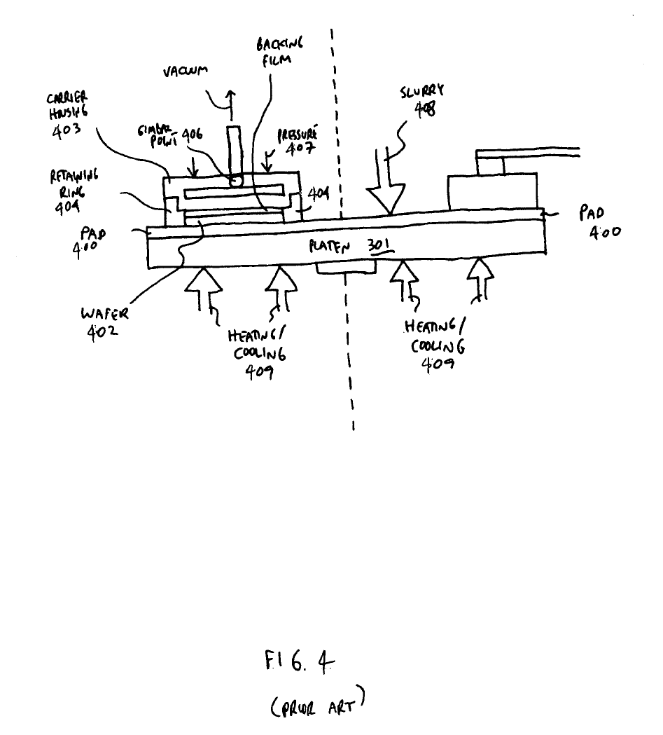

### DETAILED DESCRIPTION

A problem that has emerged in the manufacturing of semiconductor chips having shallow trenches of isolation filled with metal such as copper (Cu) or Tungsten (W) is “dishing” on the surfaces of the CMP treated metal fill regions. Dishing is one or more curvatures in a surface that has been treated with a planarization process such as CMP, and, is a departure from the objective that the finished surface be “flat”. As is known in the art, the CMP polishing of a specific surface may be a multi-step process involving a different type of CMP pad at each step. In the initial polishing steps “hard” pads (made with casting) are typically used. Subsequently, the final polishing step (or steps) typically use a “soft” CMP pad having a porous polymer layer.

According to one 130 nm manufacturing process, dishing was observed in the Copper (Cu) surfaces of Cu filled trenches, used for back end contacts, formed in an epitaxially formed oxide layer. The dishing was created by the “soft” polishing pad in the final polishing step(s). Specifically, 200 mm Politex Primar™ CMP pads manufactured by Rohm and Haas Corporation began to introduce unacceptable dishing defects to the Cu filled trenches after these pads had processed approximately 400 wafers (i.e., dishing defects began to appear once a particular pad had been used to polish about 400 wafers). The dishing problem was isolated to the “softness” of the “soft” CMP pad that was used to polish the surfaces of the trenches.

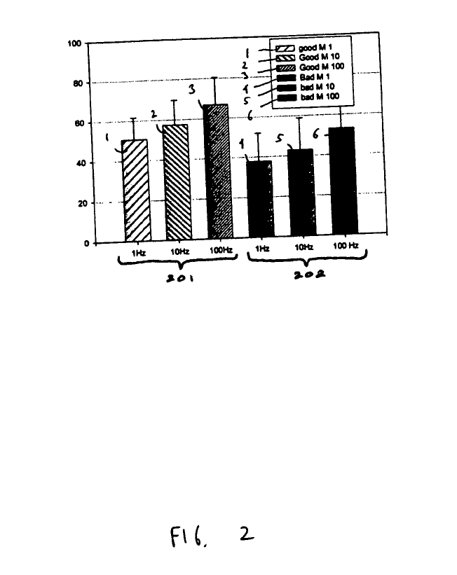

FIG. 2 elaborates on collected data that compares the dynamic modulus of “good” soft pads 201 (i.e., soft pads that did not exhibit dishing defects) against the dynamic modulus of “bad” soft pads 202 (i.e., soft pads that exhibited dishing defects). The good pads 201 clearly demonstrate higher dynamic modulus than the bad pads 202. In particular, “softer” soft pads having a dynamic modulus less than 40 MPa measured at 1 Hz, 45 MPa measured at 10 Hz, and 55 MPa measured at 100 Hz were observed to introduce unacceptable dishing defects after 400 wafers were processed while “harder” soft pads having a dynamic modulus within a range of 50 MPa to 62 MPa inclusive measured at 1 Hz, 60 MPa to 70 MPa inclusive measured at 10 Hz, and 65 MPa to 80 MPa inclusive measured at 100 Hz did not introduce such defects. The dynamic modulus of a pad is essentially a measure of the pad's hardness as tested against an applied, oscillating strain. Here, a lower dynamic modulus corresponds to a higher elasticity or “softer” pad, while, a higher dynamic modulus corresponds to a lower elasticity or “harder” pad.

A spread of softer and harder soft pads could be found in the same batch of purchased soft pads. Other potential causes of the dishing (e.g., slurry turbidity ratio and wafer location) were eliminated. Because of the relatively low number of wafers that the softer soft pads could acceptably polish, significant costs would be imposed into the manufacturing process due to frequent pad replacement. The cost of pad replacement includes not only the cost of the pad but the time expense of having a CMP tool inactive on a manufacturing floor during the pad replacement procedure (referred to by those of ordinary skill as the “cost of tool availability”).

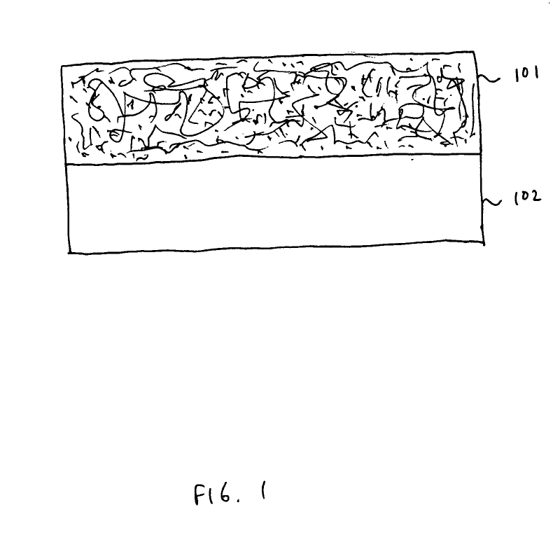

FIG. 1 shows a exemplary soft CMP pad. According to the depiction of FIG. 1, a soft CMP pad 100 includes an porous polymer layer 101 atop a substrate 102. The porous polymer layer 101 is sponge-like in that neighboring local openings in the material are frequently connected to each another. Terms such as “open cell”, “poromeric” or “reticulated cell structure” are often used to describe the porous polymer layer 101 (and/or the soft pad itself). The porous polymer layer 101 may be formed, for instance, by coating the substrate with a polyurethane polymer and applying a liquid (e.g., polyvinyl chloride) to the polyurethane polymer coating that causes the polymer within the coating to coagulate.

The coagulation of the polymer causes the formation of the porous polymer structure. In one implementation, the porous polymer layer can be viewed as having an “upper layer” of vertically oriented larger pores near the pad surface that makes contact with the wafer surface to be planarized, and, a “lower layer” of smaller pores beneath the larger vertically oriented pores. The lower layer (of smaller pores) is closer to the substrate 102 than the upper layer (of larger vertically oriented pores). The substrate 102 may be made of various materials such as non woven felt impregnated with a filler, heavy paper, woven or non woven textile, polyethylene terephthalate (Mylar™), or a film.

It is believed that the dishing problem can be solved, at least for the particular trench structure described above, with a “harder”, less elastic “soft” pad having a dynamic modulus within a range of 50 MPa to 62 MPa inclusive measured at 1 Hz, 60 MPa to 70 MPa inclusive measured at 10 Hz, and 65 MPa to 80 MPa inclusive measured at 100 Hz. In order to create such a soft pad, the exemplary pad described just above may be made to have one or more additional features that have the effect of hardening the soft pad (i.e., increasing its dynamic modulus).

One such feature is to use a polyurethane polymer having a higher concentration of “hard” segments. Here, polyurethane polymers used to form the porous polymer layer 101 of a CMP pad as described above tend to include both hard and soft segments. Examples of hard segments include cyanates (such as a isocyanate, toluene-2,4-diisocyanate, tetramethylxylylene diisocyanate, etc.) and butanediol. Examples of soft segments include methylenedicyclohexyl diisocyanate (HMDI), dimethylolpropionic acid (DMPA) and “poly-glycols” (e.g., polytetramethyleneglycol (PTMG), polyethyleneglycol (PEG)- macroglycol, polypropylene glycol (PPG)). In order to increase the dynamic modulus of the CMP pad, the concentration of the hard segments should be increased. For instance, a hard segment to soft segment ratio within a range of 1:1 to 9:1.

Another approach to increase the dynamic modulus of a CMP pad is to use a “harder” substrate 102. For instance, in the case of a non woven felt substrate that is impregnated with a filler, more “filler” material may be packed into the substrate so as to increase its packing density. This, in turn, should make the substrate harder. The filler may be composed of various materials such as carbon black, multi-walled carbon nanotube, barium sulfate (BaSO₄) and calcium carbonate (CaCO₃) talc. Filler concentrations at least as high as 10 to 50 wp, depending on polymer matrix and filler type should be capable of bringing the dynamic modulus to at least the level specific above at or above which dishing defects are avoided for processing runs greater than 400 wafers per pad change.

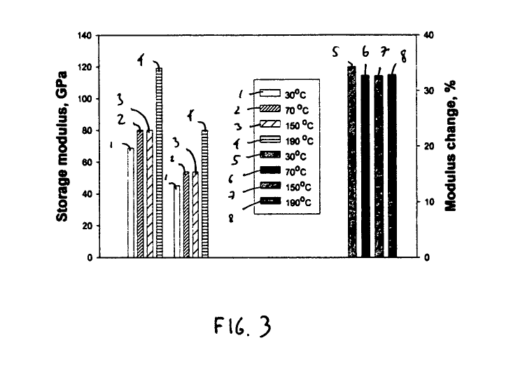

Another approach that may be used to increase the hardness of a soft or marginally soft pad is to bake the pad at higher temperatures to increase the hardness of the porous polymer layer 101. As observed in FIG. 3, at least for the Politex Prima™ pads to which the data of FIG. 3 was collected, pad baking for 1 hour at temperatures within a range of 70 to 190° C. increases storage modulus from 40 MPa to 80 MPa (measured at 1 Hz), or from 70 MPa to 120 MPa (measured at 100 Hz). Storage modulus percentage change for baking or storage temperatures within a range of 25 to 70° C. does not appear to change substantially. The storage modulus of a pad is the real part of the pad's dynamic modulus when expressed as a complex value having both real and imaginary terms.

A pad inspection qualification methodology for porous polymer pads that have been purchased from a vendor that supplies CMP pads could be implemented as follows. First, a plurality of samples of CMP pads (e.g., three) from a unit of shipment (referred to as a “batch” or “lot”) are given a Dynamic Mechanical Analysis (DMA) tensile stress analysis at 1, 10 and 100 Hz. Then, elastic storage moduli at the same 3 frequencies at room temperature (25° C.) are calculated and compared with critical minimal acceptable results so that only sufficiently hard pads are accepted. According to one approach (e.g., directed to Politex Prima™ pads) the critical minimal acceptable results are 50 MPa or higher measured at 1 Hz, 60 MPa or higher measured at 10 Hz, and 65 MPa or higher measured at 100 Hz. If any of the sampled pads fail the test the entire batch is rejected. If all the sample pads pass the test, the entire batch is accepted and CMP pads from the batch are permitted to be used for CMP on semiconductor wafers during semiconductor chip manufacturing applied to the semiconductor wafers.

Note that a batch of pads are typically shipped in some form of container (such as a box). Pad hardness can also be determined through other measurable criteria besides dynamic modulus such as pad porosity (e.g., softer pads are more porous while harder pads are less porous). Pad porosity can be correlated to dynamic modulus.

FIG. 3 shows an exemplary CMP polishing apparatus. A typical CMP tool consists of a rotating platen 301 that is covered by a pad 300. The wafer 302 is mounted upside down in a carrier 303 on a backing film. A retaining ring 304 keeps the wafer 302 in the correct horizontal position. Both, the platen 301 and the carrier 303 are rotating. The carrier 303 may also oscillate. For loading and unloading a robot system may be installed. During loading and unloading the wafer 302 is kept in the carrier by vacuum.

During chemical mechanical polishing, pressure is applied by down force on the carrier 303, transferred to the carrier 303 through the carrier axis 305 and a gimbal mechanism 306. Gas pressure or back pressure 307 is also loaded on the wafer. High points on the wafer 302 are subjected to higher pressures compared to lower points, hence, the removal rates are enhanced and planarization is achieved.

The slurry 308 is supplied on the platen 301 from above. The polishing speed depends on the temperature because heat may be generated by the chemical reaction heat and the abrasive friction. Therefore the platen 301 also has a temperature control system 309 that can adjust the temperature. This is done either by back spray technology as shown in FIG. 3 or by contact with a water cooled support and transmission ring, vacuum locked to the platen.

A typical CMP system also involves a pad conditioning tool 310 as well as a tool for the wafer cleaning after CMP. Also various end point detection systems can be integrated in the CMP tool. This can be done by measuring platen and carrier motor current and platen temperature by IR sensor.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. A batch of porous polymer chemical-mechanical polishing (CMP) pads for shipment, each of said CMP pads within said batch for use in a semiconductor chip manufacturing process, each of said CMP pads within said batch exhibiting an average dynamic modulus within a range of 65 MPa to 80 MPa inclusive when measured at 100 Hz.

2. The batch of claim 1 wherein each of said CMP pads have a hard segment to soft segment ratio of greater than 1:1.

3. The batch of claim 1 wherein each of said CMP pads comprises hard segments selected from the group consisting of:
a) a cyanate;
b) butanediol

4. The batch of claim 3 wherein said cyanate is selected from the group consisting of:
a) isocyanate
b) toluene-2,4-diisocyanate;
c) tetramethylxylylene diisocyanate

5. The batch of claim 1 wherein each of said CMP pads comprises soft segments selected from the group consisting of:
a) methylenedicyclohexyl diisocyanate (HMDI);
b) dimethylolpropionic acid (DMPA);
c) poly-glycol.

6. The batch of claim 4 wherein said poly-glycol is selected from the group consisting of:
a) polytetramethyleneglycol (PTMG);
b) polyethyleneglycol (PEG)- macroglycol;
c) polypropylene glycol (PPG).

7. The batch of claim 6 wherein each of said CMP pads comprises a substrate having a filler concentration greater than 50 wp

8. The batch of claim 1 wherein said CMP pads within said batch exhibit an average dynamic modulus within a range of 50 MPa to 62 MPa inclusive when measured at 1 Hz.

9. The batch of claim 1 wherein said CMP pads within said batch exhibit an average dynamic modulus within a range of 60 MPa to 70 MPa inclusive when measured at 10 Hz.

10. A method comprising:
receiving a shipped batch of porous polymer chemical-mechanical polishing (CMP) pads for use in a semiconductor chip manufacturing process, each of said CMP pads within said batch exhibiting an average dynamic modulus within a range of 65 MPa to 80 MPa inclusive when measured at 100 Hz; and,
processing a plurality of semiconductor wafers with said pads to manufacture a plurality of semiconductor chips, said processing comprising polishing a Cu surface.

11. The method of claim 10 wherein each of said CMP pads comprise a hard segment to soft segment ratio of greater than 1:1.

12. The method of claim 10 wherein each of said CMN pads comprises hard segments selected from the group consisting of:
a) a cyanate;
b) butanediol

13. The method of claim 12 wherein said cyanate is selected from the group consisting of:
a) isocyanate
b) toluene-2,4-diisocyanate;
c) tetramethylxylylene diisocyanate

14. The method of claim 10 wherein each of said CMP pads comprises soft segments selected from the group consisting of:
a) methylenedicyclohexyl diisocyanate (HMDI);
b) dimethylolpropionic acid (DMPA);
c) poly-glycol.

15. The method of claim 14 wherein said poly-glycol is selected from the group consisting of:
a) polytetramethyleneglycol (PTMG);
b) polyethyleneglycol (PEG)- macroglycol;
c) polypropylene glycol (PPG).

16. The method of claim 10 wherein each of said CMP pads comprises a substrate having a filler concentration greater than 10 wp.

17. The method of claim 16 wherein each of said CMP pads comprises a substrate having a filler concentration greater than 50 wp

18. The method of claim 16 wherein said filler is selected from the group consisting of:
carbon black;
multi-walled carbon nanotubes;
barium sulfate (BaSO₄);
calcium carbonate (CaCO₃) talc.

19. A method comprising:
receiving a batch of porous polymer CMP pads;
qualifying said batch of CMP pads, said qualifying comprising making a determination that each of said batch's CMP pads have a hardness that will demonstrate a dynamic modulus within a range of 65 MPa to 80 MPa inclusive when measured at 100 Hz;
processing a plurality of semiconductor wafers and, for each of said wafers, polishing a surface of a metal region disposed in a trench formed in a region of dielectric with a CMP pad taken from said batch.

20. The method of claim 19 wherein each of said CMP pads from said batch comprise a hard segment to soft segment ratio of greater than 1:1.

21. The method of claim 19 wherein each of said CMP pads comprises a substrate having a filler concentration greater than 10 wp.

22. The method of claim 19 wherein each of said CMP pads comprises a substrate having a filler concentration greater than 50 wp.
